(19) United States
(12) Patent Application Publication
(10) Pub. No.: US 2021/0408999 A1
(43) Pub. Date: Dec. 30, 2021

(54) ELASTIC WAVE DEVICE, SPLITTER, AND COMMUNICATION APPARATUS

(71) Applicant: KYOCERA Corporation, Kyoto-shi, Kyoto (JP)

(72) Inventor: Motoki ITO, Ikoma-shi, Nara (JP)

(21) Appl. No.: 17/291,080

(22) PCT Filed: Oct. 3, 2019
(86) PCT No.: PCT/JP2019/039104

§ 371 Date: May 4, 2021

(30) Foreign Application Priority Data
Nov. 5, 2018 (JP) 2018-208163

(51) Int. Cl. H03H 9/145; H03H 9/25; H03H 9/54; H03H 9/02; H03H 9/64

(52) U.S. Cl. CPC H03H 9/14541; H03H 9/25; H03H 9/6483; H03H 9/02275; H03H 9/54

(57) ABSTRACT

An elastic wave device includes a substrate, a multilayer film located on the substrate, a piezoelectric layer located on the multilayer film, resonators located on the piezoelectric layer and including an IDT electrode, and a protective film located on the resonators. The resonators include a first resonator and a second resonator having a higher resonant frequency than the first resonator. A thickness of the protective film on the first resonator is larger than the thickness of the protective film on the second resonator.

### TECHNICAL FIELD

The present disclosure relates to an elastic wave device which is an electronic component that uses an elastic wave, a splitter including the elastic wave device, and a communication apparatus.

### BACKGROUND ART

An elastic wave device is known which applies a voltage to an IDT (interdigital transducer) electrode on a piezoelectric body to produce an elastic wave that propagates through the piezoelectric body. An IDT electrode includes a pair of comb-teeth electrodes. The comb-teeth electrodes of the pair each have a plurality of electrode fingers, and are arranged such that the pluralities of electrode fingers interdigitate with each other. In an elastic wave device, a standing wave of an elastic wave having a wavelength that is twice a pitch of the electrode fingers is formed. The frequency of this standing wave serves as a resonant frequency. Therefore, a resonance point of the elastic wave device is defined by the pitch of the electrode fingers.

An elastic wave device that implements resonance at a relatively high frequency with respect to a pitch of electrode fingers is desired in recent years.

### SUMMARY OF INVENTION

### Solution to Problem

An elastic wave device according to one aspect of the present disclosure includes a substrate, a multilayer film located on the substrate, a piezoelectric layer located on the multilayer film, a plurality of resonators located on the piezoelectric layer and including an IDT electrode, and a protective film located on the plurality of resonators. The multilayer film includes a low acoustic impedance layer and a high acoustic impedance layer that are alternately stacked. The plurality of resonators include a first resonator and a second resonator that have different resonant frequencies. The first resonator has a lower resonant frequency than the second resonator. A thickness of the protective film on the second resonator is larger than the thickness of the protective film on the first resonator.

A splitter according to an aspect of the present disclosure includes an antenna terminal, a transmission filter configured to perform filtering on a signal to be output to the antenna terminal, and a reception filter configured to perform filtering on a signal input from the antenna terminal. At least one of the transmission filter or the reception filter includes the elastic wave device.

A communication apparatus according to an aspect of the present disclosure includes an antenna, the splitter of which the antenna terminal is connected to the antenna, and an IC connected to the transmission filter and the reception filter, on an opposite side from the antenna terminal in a signal path.

### BRIEF DESCRIPTION OF DRAWINGS

FIG. 1(a) and FIG. 1(b) are plan views of an elastic wave device according to an embodiment.

FIG. 2 is a cross-sectional view of the elastic wave device taken along lines II-II in FIG. 1.

FIG. 3 is a graph illustrating a correlation between a pitch and a resonant frequency of a resonator.

FIG. 4(a) is a graph illustrating a correlation between a thickness of a protective film and impedance, and FIG. 4(b) is a graph illustrating a correlation between the thickness of the protective film and a phase.

FIG. 5 is a graph illustrating a correlation between the thickness of the protective film and a maximum phase value.

FIG. 6A is a diagram illustrating simulation results obtained when a pitch p is changed.

FIG. 6B is a diagram illustrating simulation results obtained when the pitch p is changed.

FIG. 7(a) and FIG. 7(b) are diagrams illustrating simulation results obtained when a thickness of a conductive layer is changed.

FIG. 8(a) and FIG. 8(b) are diagrams illustrating simulation results obtained when a duty is changed.

FIG. 9 is a circuit diagram schematically illustrating a configuration of a splitter serving as an application example of the elastic wave device illustrated in FIG. 1.

FIG. 10 is a circuit diagram schematically illustrating a configuration of a communication apparatus serving as an application example of the elastic wave device illustrated in FIG. 1.

FIG. 11A is a diagram illustrating simulation results obtained when the pitch p is changed.

FIG. 11B is a diagram illustrating simulation results obtained when the pitch p is changed.

### DESCRIPTION OF EMBODIMENTS

An embodiment according to the present disclosure will be described below with reference to the drawings. The drawings used in the description below are schematic, and dimension ratios and the like in the drawings do not necessarily coincide with the actual ones.

Any direction of an elastic wave device according to the present disclosure may be set as the upper direction or the lower direction. However, for the sake of convenience, an orthogonal coordinate system constituted by an axis D1, an axis D2, and an axis D3 is defined. On the assumption that a positive side along the axis D3 is the upper direction, terms “upper surface”, “lower surface”, and so on are used. The term “plan view” or “plan perspective view” refers to viewing in a direction of the axis D3 unless otherwise noted. The axis D1 is defined to be parallel with a propagation direction of an elastic wave that propagates along an upper surface of a piezoelectric layer described below. The axis D2 is defined to be parallel with the upper surface of the piezoelectric layer and to be orthogonal to the axis D1. The axis D3 is defined to be orthogonal to the upper surface of the piezoelectric layer.

(Overall Configuration of Elastic Wave Device)

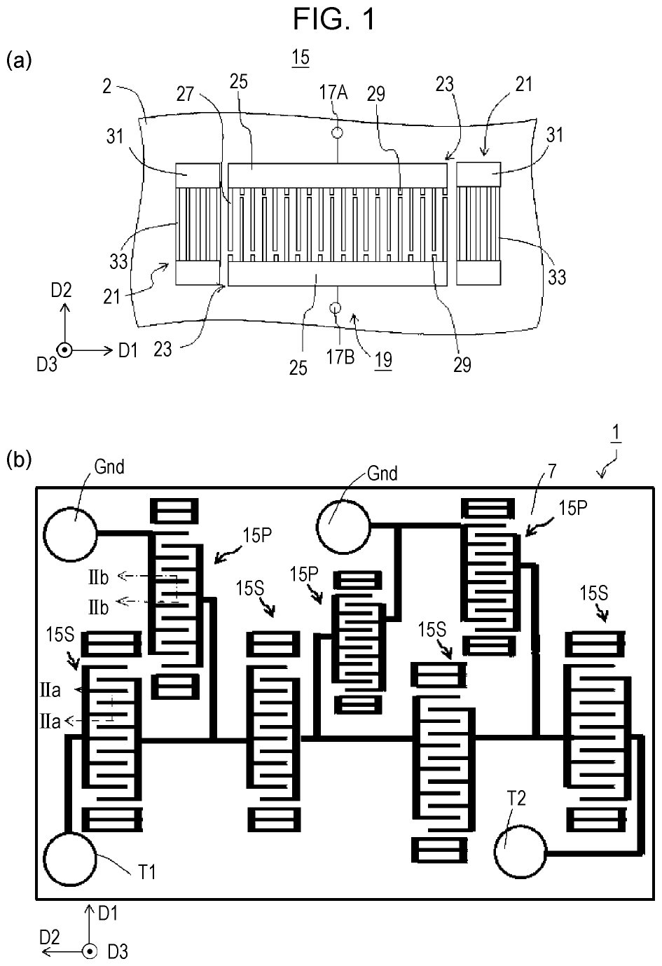

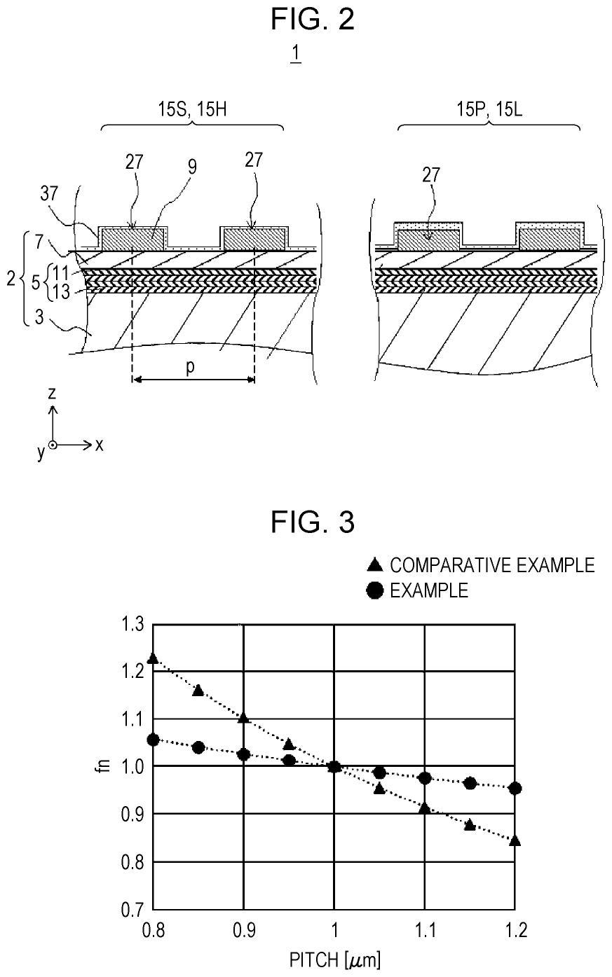

FIG. 1 is a plan view of a configuration of major components of an elastic wave device 1. FIG. 1(a) illustrates a configuration of a resonator described below. FIG. 1(b) illustrates an example in which a plurality of resonators illustrated in FIG. 1(a) are disposed to constitute a ladder filter. That is, series resonators 15S and parallel resonators 15P are connected to each other in a ladder form. The series resonators 15S are referred to as second resonators or resonators 15H in some cases. The parallel resonators 15P having a lower resonant frequency than the series resonators 15S are referred to as first resonators or resonators 15L in some cases. FIG. 2 is a cross-sectional view taken along lines II-II (line IIa-IIa and line IIb-IIb) in FIG. 1(b).

The elastic wave device 1 includes, for example, a substrate 3 (FIG. 2), a multilayer film 5 (FIG. 2) located on the substrate 3, a piezoelectric layer 7 located on the multilayer film 5, and a conductive layer 9 located on the piezoelectric layer 7. Each layer has, for example, a substantially uniform thickness. A composite of the substrate 3, the multilayer film 5, and the piezoelectric layer 7 is referred to as an affixed substrate 2 (FIG. 2) in some cases.

In the elastic wave device 1, a voltage is applied to the conductive layer 9, so that an elastic wave that propagates through the piezoelectric layer 7 is excited. The elastic wave device 1 is included in, for example, a resonator and/or a filter that uses this elastic wave. The multilayer film 5 contributes to trapping energy of the elastic wave in the piezoelectric layer 7 by reflecting the elastic wave, for example. The substrate 3 contributes to increasing the strength of the multilayer film 5 and the piezoelectric layer 7, for example.

The elastic wave device 1 includes a plurality of resonators 15 illustrated in FIG. 1(a). In this example, the plurality of resonators 15 are electrically connected to each other to constitute a filter. Specifically, as illustrated in FIG. 1(b), the series resonators 15S are connected in series with each other between a terminal T1 and a terminal T2. The parallel resonators 15P are connected in parallel with the series resonators 15S between the series resonators 15S and a reference potential Gnd. In such a configuration, the plurality of resonators 15 (15S and 15P) constitute a ladder filter. Note that FIG. 1(b) illustrates the structure of the resonators 15 in a simplified manner.

(Schematic Configuration of Affixed Substrate)

The substrate 3 does not directly influence electrical characteristics of the elastic wave device 1. Accordingly, a material and dimensions of the substrate 3 may be appropriately set. The material of the substrate 3 is, for example, an insulating material. The insulating material is, for example, a resin or a ceramic. The substrate 3 may be composed of a material having a smaller thermal expansion coefficient than the piezoelectric layer 7 or the like. In this case, for example, a probability of frequency characteristics of the elastic wave device 1 being changed by a temperature change can be reduced. Examples of such a material may include a semiconductor such as silicon, a single crystal such as sapphire, and a ceramic such as sintered aluminum oxide. Note that the substrate 3 may be constituted by a plurality of stacked layers composed of materials that are different from each other. The substrate 3 has a greater thickness than the piezoelectric layer 7, for example.

The multilayer film 5 includes low acoustic impedance layers 11 and high acoustic impedance layers 13 that are alternately stacked. Thus, interfaces between these layers have a relatively high reflectivity for an elastic wave. As a result, leakage of the elastic wave that propagates through the piezoelectric layer 7, for example, is reduced. Silicon dioxide (SiO₂) may be exemplified as a material of the low acoustic impedance layers 11. Tantalum pentoxide (Ta₂O₅), hafnium oxide (HfO₂), zirconium oxide (ZrO₂), or titanium oxide (TiO₂) may be exemplified as a material of the high acoustic impedance layers 13.

The number of stacked layers in the multilayer film 5 may be appropriately set. For example, the total number of low and high acoustic impedance layers 11 and 13 that are stacked in the multilayer film 5 may be more than or equal to two layers and less than or equal to twelve layers. The total number of stacked layers in the multilayer film 5 may be an even number or an odd number. However, the layer that is in contact with the piezoelectric layer 7 is the low acoustic impedance layer 11. The layer that is in contact with the substrate 3 may be either the low acoustic impedance layer 11 or the high acoustic impedance layer 13. A supplementary film may be inserted between the individual layers, between the substrate 3 and the multilayer film 5, or between the multilayer film 5 and the piezoelectric layer 7 for the purpose of close contact or of preventing diffusion. In such a case, the supplementary film may be thin (approximately 0.01λ, or less) enough not to influence the characteristics of the elastic wave device 1.

The piezoelectric layer 7 is composed of a single crystal of lithium tantalate (LiTaO₃, hereinafter, referred to as LT) or lithium niobate (LiNbO₃, hereinafter, referred to as LN).

In the case where LT is used as the piezoelectric layer 7, the cut angles are, for example, (0°±10°, 0° or greater and 55° or smaller, 0°±10°) in Euler angles. In another aspect, LT is of rotated Y-cut X-propagation. The Y axis is inclined with respect to the normal (the axis D3) of the piezoelectric layer 7 by an angle of 90° or more and 145°. The X axis is substantially parallel with the upper surface (the axis D1) of the piezoelectric layer 7. Note that the X axis and the axis D1 may be inclined by an angle of −10° or more and 10° or less on an X-Z plane or a D1-D2 plane.

In the case where LN is used as the piezoelectric layer 7, the cut angles are (0, 0, ψ) in Euler angles, where ψ is 0° or more and 360° or less. In another aspect, a Z-cut substrate may be used.

The thickness of the piezoelectric layer 7 is relatively thin and, for example, is greater than or equal to 0.175λ and less than or equal to 0.3λ, where λ described below serves as a reference. Such settings of the cut angles and the thickness of the piezoelectric layer 7 enable the use of a wave in an oscillation mode close to a slab mode as an elastic wave. Specifically, the use of an Al-mode Lamb wave is enabled. Therefore, a relatively high resonant frequency (for example, 5 GHz or higher) with respective to the pitch of electrode fingers described below can be implemented.

In the present embodiment, the case of using LT as the piezoelectric layer 7 will be described by way of example below.

(Schematic Configuration of Conductive Layer)

The conductive layer 9 is formed using a metal, for example. The metal may be of an appropriate kind, and is, for example, aluminum (Al) or an alloy (Al alloy) containing Al as a main ingredient. The Al alloy is, for example, an Al-copper (Cu) alloy. The conductive layer 9 may be constituted by a plurality of metal layers. A relatively thin layer composed of titanium (Ti) may be disposed between the Al or Al alloy and the piezoelectric layer 7 to increase the bonding of these layers.

The conductive layer 9 is formed to constitute the resonator 15 in the example of FIG. 1(a). The resonator 15 is configured as a so-called one-port elastic wave resonator. When receiving an electric signal having a predetermined frequency from one of terminals 17A and 17B, which are illustrated conceptually and schematically, the resonator 15 is able to cause resonance and output a signal produced by the resonance from the other of the terminals 17A and 17B.

The conductive layer 9 (the resonator 15) includes, for example, an IDT electrode 19 and a pair of reflectors 21 located on the respective sides of the IDT electrode 19.

The IDT electrode 19 includes a pair of comb-teeth electrodes 23. Each of the comb-teeth electrodes 23 includes, for example, a busbar 25, a plurality of electrode fingers 27 extending from the busbar 25 in parallel with each other, and dummy electrodes 29 protruding from the busbar 25 between the plurality of electrode fingers 27. The comb-teeth electrodes 23 of the pair are arranged such that the pluralities of electrode fingers 27 interdigitate with (intersect with) each other.

The busbar 25 has, for example, an elongated shape that has a substantially uniform width and linearly extends in a direction (direction of the axis D1) in which an elastic wave propagates. The pair of busbars 25 face each other in a direction (direction of the axis D2) orthogonal to the elastic wave propagation direction. The busbar 25 may have a varying width or may be inclined with respect to the elastic wave propagation direction.

Each of the electrode fingers 27 has, for example, an elongated shape that has a substantially uniform width and linearly extends in the direction (direction of the axis D2) orthogonal to the elastic wave propagation direction. In each of the comb-teeth electrodes 23, the plurality of electrode fingers 27 are arranged in the elastic wave propagation direction. The plurality of electrode fingers 27 of one of the comb-teeth electrodes 23 and the plurality of electrode fingers 27 of the other comb-teeth electrode 23 are arranged alternately with each other as a rule.

A pitch p of the plurality of electrode fingers 27 (for example, a distance between centers of two electrode fingers 27 adjacent to each other) is constant in the IDT electrode 19 as a rule. A narrow pitch portion in which the pitch p is narrower than that in most of the other portions or a wide pitch portion in which the pitch p is wider than that in most of the other portions may be provided in a part of the IDT electrode 19.

The term “pitch p” refers to a pitch (between most of the plurality of electrode fingers 27) in a portion other than an exceptional portion such as the aforementioned narrow pitch portion or wide pitch portion below unless otherwise noted. If most of the plurality of electrode fingers 27 except for those in the exceptional portion have different pitches, the average value of the pitches between the most of the plurality of electrode fingers 27 may be used as the value of the pitch p.

The plurality of electrode fingers 27 have lengths substantially equal to each other, for example. So-called apodization for changing the lengths (in another aspect, intersecting widths) of the plurality of electrode fingers 27 depending on the position in the propagation direction may be performed on the IDT electrode 19.

For example, the dummy electrodes 29 have a substantially uniform width and protrude in a direction orthogonal to the elastic wave propagation direction. Distal ends of the dummy electrodes 29 of one of the comb-teeth electrodes 23 face distal ends of the respective electrode fingers 27 of the other comb-teeth electrode 23 with gaps therebetween. The IDT electrode 19 may be an IDT electrode not including the dummy electrodes 29.

The pair of reflectors 21 are located on the respective sides of the plurality of IDT electrodes 19 in the elastic wave propagation direction. Each of the reflectors 21 has, for example, a grating shape. Specifically, the reflector 21 includes a pair of busbars 31 facing each other, and a plurality of strip electrodes 33 extending between the pair of busbars 31. A pitch between the plurality of strip electrodes 33 and a pitch between the electrode finger 27 and the strip electrode 33 adjacent to each other are substantially equal to the pitch between the plurality of electrode fingers 27 as a rule.

The upper surface of the piezoelectric layer 7 is covered with a protective film 37 from above the conductive layer 9. The protective film 37 is composed of a material having a lower acoustic velocity than the piezoelectric layer 7. Examples of such a material include SiO₂, Si₃N₄, Si, etc. The protective film 37 may be disposed only right on the conductive layer 9 or may be disposed also between the electrode fingers 27 constituted by the conductive layer 9. In the case where the protective film 37 is disposed also between the electrode fingers 27, the protective film 37 may be composed of an insulating material. The protective film 37 may be a stacked body of a plurality of layers composed of these materials.

The protective film 37 may be a film for simply suppressing corrosion of the conductive layer 9 or may be a film that contributes to temperature compensation. To clarify the acoustic boundary between the conductive layer 9 and the protective film 37 and to improve the elastic wave reflectance coefficient, a supplementary film composed of an insulator or a metal may be provided on the upper surfaces or lower surfaces of the IDT electrode 19 and the reflectors 21.

The thickness of such a protective film 37 right on the series resonators 15S differs from the thickness of the protective film 37 right on the parallel resonators 15P. Specifically, the thickness right on the parallel resonators 15P is greater than the thickness right on the series resonators 15S. Hereinafter, the term “the thickness of the protective film 37” refers to a thickness on the electrode fingers of the resonator unless otherwise noted. The thickness of the protective film 37 will be described later.

In this example, the protective film 37 is located also between the electrode fingers 27. An upper surface of the protective film 37 between the electrode fingers 27 is located on the lower side than the upper surface of the conductor layer 9. The thickness of the protective film 37 on the electrode fingers 27 is sufficiently thin (for example, ½ or less), compared with the thickness of the electrode fingers 27.

The configuration illustrated in FIGS. 1 and 2 may be appropriately configured as a package. The package may be a package obtained by, for example, mounting the illustrated components with a gap therebetween such that the components face the upper surface of the piezoelectric layer 7 over a substrate not illustrated and by applying resin sealing to the resultant object, or may be a package of a wafer level package type in which a box-shaped cover is provided over the piezoelectric layer 7.

(Use of Slab Mode)

When a voltage is applied to the pair of comb-teeth electrodes 23, the voltage is applied to the piezoelectric layer 7 by the plurality of electrode fingers 27 and the piezoelectric layer 7 that is a piezoelectric body oscillates. Consequently, an elastic wave that propagates in the direction of the axis D1 is excited. The elastic wave is reflected by the plurality of electrode fingers 27. Then, a standing wave occurs which has a half wavelength (λ/2) that is approximately equal to the pitch p between the plurality of electrode fingers 27. An electric signal produced in the piezoelectric layer 7 by the standing wave is extracted by the plurality of electrode fingers 27. According to such a principle, the elastic wave device 1 functions as a resonator having, as a resonant frequency, the frequency of the elastic wave having the half wavelength equal to the pitch p. Note that λ is a symbol usually representing a wavelength. The actual wavelength of the elastic wave sometimes deviates from 2p. However, in the case where the symbol λ is used below, λ indicates 2p unless otherwise noted.

As described above, the piezoelectric layer 7 is relatively thin, and Euler angles of the piezoelectric layer 7 are (0°±10°, from 0° to 55°, 0°±10°). Thus, the use of a slab-mode elastic wave is enabled. A propagation velocity (acoustic velocity) of the slab-mode elastic wave is higher than a propagation velocity of a general SAW (Surface Acoustic Wave). For example, the propagation velocity of the general SAW is 3000 to 4000 m/s, whereas the propagation velocity of the slab-mode elastic wave is 10000 m/s or higher. Therefore, with the pitch p that is substantially equal to the pitch of the related art, resonance in a higher frequency region compared with that of the related art can be implemented. For example, with the pitch p of 1 μm or greater, the resonant frequency of 5 GHz or higher can be implemented.

(Settings of Material and Thickness of Each Layer)

To implement resonance in a relatively high frequency region (5 GHz or higher, for example) using the slab-mode elastic wave, there are conditions on the combination of the material and the thickness of the multilayer film 5; the Euler angles, the material, and the thickness of a piezoelectric body layer (the piezoelectric layer 7 in the present embodiment); and the thickness of the conductive layer 9.

For example, under the conditions below, resonance at 5 GHz can be achieved without any spurious near the resonant frequency and the anti-resonant frequency.

Piezoelectric Layer:
Material: LiTaO₃
Thickness: 0.2λ
Euler angles: (0, 24, 0)

Multilayer Film:
Materials: Two kinds (SiO₂, Ta₂O₅)
Thickness: SiO₂ layer 0.10λ, Ta₂O₅ layer 0.98λ
Number of stacked layers: Eight layers

Conductive Layer:
Material: Al
Thickness: 0.06λ
Pitch p: 1 μm (λ=2 μm)

The number of stacked layers is the total number of two kinds of layers (=4 in the example of FIG. 2, for example). The following simulation is performed using the pitch p of 1 μm. However, even if the pitch is changed, as long as the actual film thickness is changed in accordance with the wavelength represented by λ=2p, the similar result is achieved although the frequency dependence of the resonance characteristics merely shifts as a whole. That is, the similar result can be achieved also when normalization is performed based on the wavelength or the pitch.

In addition to the example above, for example, also in the case where the pitch is 0.9 μm to 1.4 μm under conditions below, resonance at 5 GHz or higher and the state without any ripple near the resonant frequency and the anti-resonant frequency can be achieved. As for the conditions below, the conditions are listed using “/” in an order of the material of the piezoelectric layer 7, the thickness of the piezoelectric layer 7, the material of the low acoustic impedance layer 11, the thickness of the low acoustic impedance layer 11, the material of the high acoustic impedance layer 13, and the thickness of the high acoustic impedance layer 13.

Other conditions 1: LT/0.175λ/SiO₂/0.09λ/Ta₂O₅/0.07λ

Other conditions 2: LT/0.2λ/SiO₂/0.1λ/HfO₂/0.08λ

Other conditions 3: LN/0.19λ/SiO₂/0.1λ/Ta₂O₅/0.07λ

Other conditions 4: LN/0.2λ/SiO₂/0.06λ/HfO₂/0.095λ

Simulation is performed by setting the thickness of the protective film 37 to be uniform for the series resonators 15S and the parallel resonators 15P unless otherwise noted.

(Regarding Control of Resonant Frequency in Slab Mode)

In the case where the elastic wave device 1 includes the resonators 15 having resonant frequencies different from each other, the thickness of the protective film 37 is made different to adjust the frequency with the frequency characteristics being maintained. In this example, the elastic wave device 1 includes the series resonators 15S and the parallel resonators 15P, and the thickness of the protective film 37 that covers the parallel resonators 15P having a lower resonant frequency is made smaller than that for the series resonators 15S.

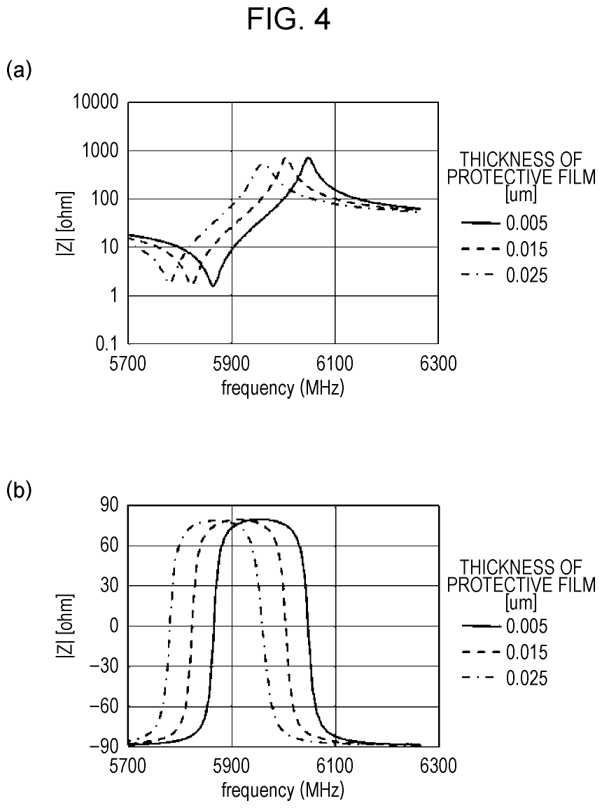

In general, to change the frequency of the resonator 15, the pitch of the electrode fingers 27 is changed. In FIG. 3, a rate of change of the resonant frequency in response to a change of the pitch of the electrode fingers 27 of the resonator 15 is measured. In FIG. 3, the horizontal axis represents the pitch (unit: μm), and the vertical axis represents a rate of change of the resonant frequency with respect to the resonant frequency in the case where the pitch is 1 μm. As a comparative example, an elastic wave device including the piezoelectric layer 7 having a thickness of 0.2 mm is fabricated, and the frequency characteristics are measured similarly. In the comparative example, the pitch is set to 1 μm. Since the resonant frequency in the comparative example differs from the resonant frequency in the example, the vertical axis in FIG. 3 is presented based on normalization by the resonant frequency. It is assumed that the thickness of the protective film 37 is uniform.

As a result, in the case of the elastic wave device 1 according to the present embodiment, the resonant frequency changes from 6000 MHz to 6150 MHz when the pitch changes by 0.1 μm. That is, the rate of change with respect to the reference resonant frequency is 2.5%. Similarly, in the case of the elastic wave device according to the comparative example, the rate of change of the resonant frequency in response to a change of the pitch by 0.1 μm is 10%. That is, when the resonant frequency is 6000 MHz, the resonant frequency changes to 6600 MHz. As described above, it is confirmed that the resonant frequency of the elastic wave device 1 according to the present embodiment is less likely to change in response to a change of the pitch than that of a comparative example. The phenomenon that the rate of change of the resonant frequency in response to the change of the pitch reduces in this manner occurs when the thickness of the piezoelectric layer 7 is less than or equal to 0.6λ. The phenomenon is more marked when the thickness of the piezoelectric layer 7 is less than or equal to 0.5λ.

To implement the slab-mode resonance characteristics, the thicknesses of the piezoelectric layer 7, and the low acoustic impedance layer 11 and the high acoustic impedance layer 13 of the multilayer film 5 relative to λ are required to be set to a particular combination. If the thicknesses deviate from the combination, a large ripple occurs. That is, when the resonators 15 having different frequencies are included in the same affixed substrate 2, the relative film thicknesses of the piezoelectric layer 7 and the multilayer film 5 of at least one of the resonators 15 deviate from appropriate values. As a result, the waveform of the resonance characteristics distorts and a ripple occurs.

Specifically, a discussion will be given using a resonator 15H (second resonator) having a higher resonant frequency and a resonator 15L (first resonator) having a lower resonant frequency as an example. In the case where the affixed substrate 2 suitable for the pitch in the resonator 15H is used, the pitch in the resonator 15L is made larger than that in the resonator 15H in order to lower the resonant frequency of the resonator 15L. In such a case, λ increases, and the resonant frequency changes toward the lower frequency side. The relative film thickness of the piezoelectric layer 7 with respect to λ decreases as λ increases. The smaller the relative film thickness of the piezoelectric layer 7 with respect to the wavelength λ, the more the resonant frequency shifts toward the higher frequency side. Thus, the resonant frequency of the resonator 15L becomes higher than an expected frequency designed based on the pitch. If the pitch in the resonator 15L is further increased to correct this, the ratio to the wavelength greatly deviates from that of each layer of the multilayer film 5 and a ripple occurs in the resonance waveform of the resonator 15L.

In the case where the affixed substrate 2 suitable for the resonator 15L is used, the resonant frequency of the resonator 15H conversely lowers. This is not suitable when achievement of a higher frequency is attempted.

As described above, in the case of the elastic wave element 1 according to the present embodiment, even when the pitch is changed, the rate of change of the resonant frequency is small. In addition, the waveform of the frequency characteristics (impedance characteristics) distorts because of the change of the pitch, and a ripple occurs.

A technique of changing the thickness of the conductive layer 9 and a technique of changing the duty of the resonator 15 for the purpose of changing the resonant frequency are also known. Either method is for controlling the thickness or dimension relative to λ. Thus, as in the case of the pitch, when the relative ratio to λ is adjusted, the waveform of the frequency characteristics distorts and a ripple occurs.

Accordingly, the resonant frequency of the resonator 15 is adjusted by adjusting the thickness of the protective film 37. If the affixed substrate 2 is designed to satisfy conditions close to the conditions for the resonator 15H, the design is beneficial in achieving a higher frequency.

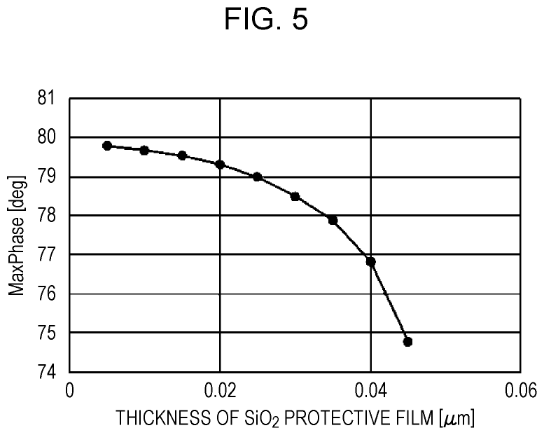

FIG. 4 illustrates the frequency characteristics of the resonator obtained when the film thickness of the protective film 37 is set differently. FIG. 4(a) illustrates impedance characteristics. The horizontal axis represents a frequency (unit: MHz), and the vertical axis represents an impedance (unit: ohm). FIG. 4(b) illustrates phase characteristics. The horizontal axis represents a frequency (unit: MHz), and the vertical axis represents a phase (unit: deg). As illustrated in FIG. 4, it is confirmed that when the film thickness of the protective film 37 is changed from 0.005 μm to 0.025 μm, the resonant frequency shifts toward the lower frequency side as the film thickness increases. Specifically, by changing the protective film thickness by 100 Å (that is, 0.01 p), the resonant frequency can be shifted toward the lower frequency side by 44 MHz. It can also be confirmed that the waveform does not distort even when the thickness of the protective film 37 is changed. In other words, it is confirmed that a new ripple does not occur when the thickness of the protective film 37 is changed.

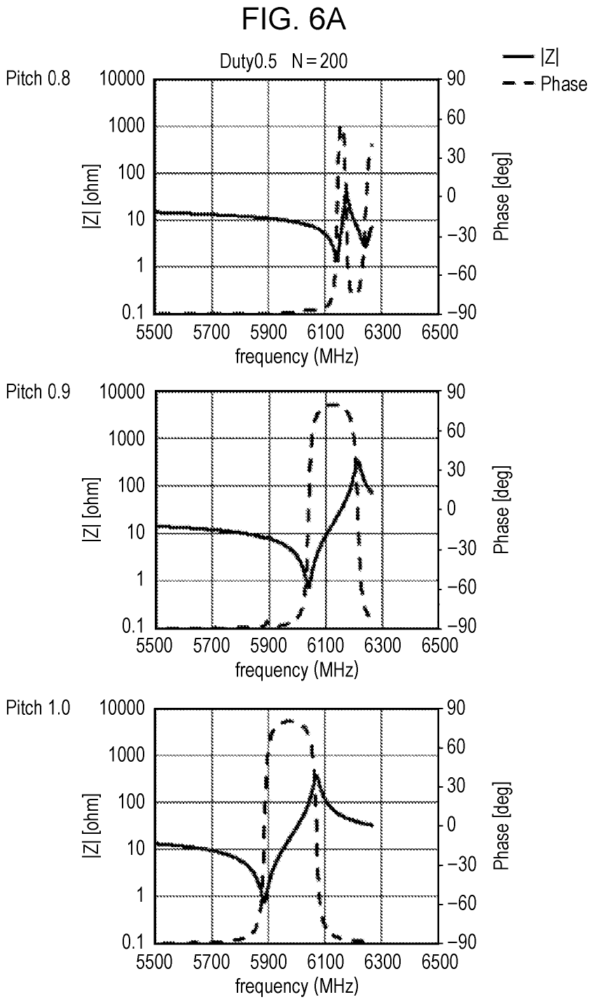

On the other hand, the loss increases (the maximum phase decreases) as the thickness of the protective film 37 increases. FIG. 5 is a graph illustrating a correlation between the thickness of the protective film 37 and the maximum phase. In FIG. 5, the horizontal axis represents the thickness (unit: μm) of the protective film 37, and the vertical axis represents the maximum phase (unit: deg). As is apparent from FIG. 5, it is confirmed that the maximum phase abruptly decreases when the thickness of the protective film 37 exceeds 0.04 μm (that is, 0.04p when the thickness is converted using the pitch p). As described above, by making the thickness of the protective film 37 greater on the electrode fingers 27 of the resonators L (the parallel resonators 15P in the example illustrated in FIG. 1) than on the electrode fingers 27 of the resonators H (the series resonators 15S in the example illustrated in FIG. 1) and by setting the thickness to be less than or equal to 0.04p, the resonant frequencies of both the resonators 15H and the resonators 15L can be adjusted to desired resonant frequencies and further the occurrence of the loss can be suppressed. Further, in the case where the thickness is set to be less than or equal to 0.025p, the maximum phase does not decrease in a quadratic function fashion. Thus, a decrease in the loss can be further suppressed.

### First Modification

According to the embodiment described above, the case where the frequency adjustment is performed on the resonator 15 by adjusting the thickness of the protective film 37 alone has been described. However, another frequency adjustment method may be used in combination.

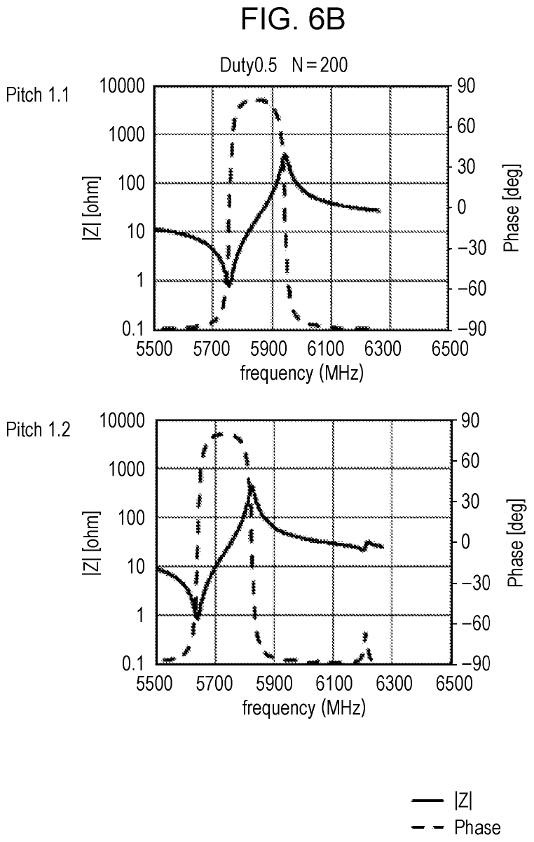

First, frequency adjustment based on the pitch p will be discussed. FIG. 6 (FIG. 6A and FIG. 6B) illustrates impedance characteristics and phase characteristics obtained when the pitch p is changed in the resonator 15. FIG. 6A illustrates the characteristics obtained when the pitch is set to 0.8 μm, 0.9 μm, and 1.0 μm (that is, when the pitch is set to 0.8p, 0.9p, and p in the case where 1.0 μm is set as a reference). FIG. 6B illustrates the characteristics obtained when the pitch is set to 1.1 μm and 1.2 μm (when the pitch is set to 1.1p and 1.2p).

In FIG. 6, the horizontal axis represents the normalized frequency, the left vertical axis represents the impedance (unit: ohm), and the right vertical axis represents the phase (unit: deg). As is apparent from FIG. 6, it is confirmed that spurious starts to appear on a lower frequency side of the resonant frequency when the pitch p is changed from 1.0p to 0.9p and the waveform itself distorts when the pitch p is changed to 0.8p. Accordingly, the lower limit value of the pitch p is set to be greater than or equal to 0.9p. On the other hand, spurious starts to appear near the anti-resonant frequency when the pitch p is changed from 1.0p to 1.2p. Accordingly, the upper limit value of the pitch p is set to be greater than or equal to 1.2p.

As described before, in response to a change of the pitch p, the rate of change of the frequency is small and the waveform distorts. However, setting the pitch p to be greater than or equal to 0.9p and less than or equal to 1.2p enables frequency adjustment to be compensated for while maintaining the waveform.

The thickness of the protective film 37 may be set in the manner of the above-described embodiment to satisfy relationships below, where p1 and fr1 respectively denote the pitch and the resonant frequency of one resonator 15 and p2 and fr2 respectively denote the pitch and the resonant frequency of another resonator 15.

0.9p1≤p2≤1.2p1

|p2/p1−1|≥|fr2/fr1−1|

That is, by changing the pitch at a degree greater than or equal to a rate of change of the resonant frequency within a range free from the waveform distortion and by adjusting the thickness of the protective film 37, effects based on an effect of adjustment of the thickness of the protective film 37 and an effect of adjustment of the pitch can be effectively obtained.

In the case where the plurality of series resonators 15s are present as illustrated in FIG. 1(b) and resonant frequencies thereof are shifted from one another, the pitch of the resonator 15 that exhibits the resonant frequency near the average value among the series resonators 15s may be set as the reference.

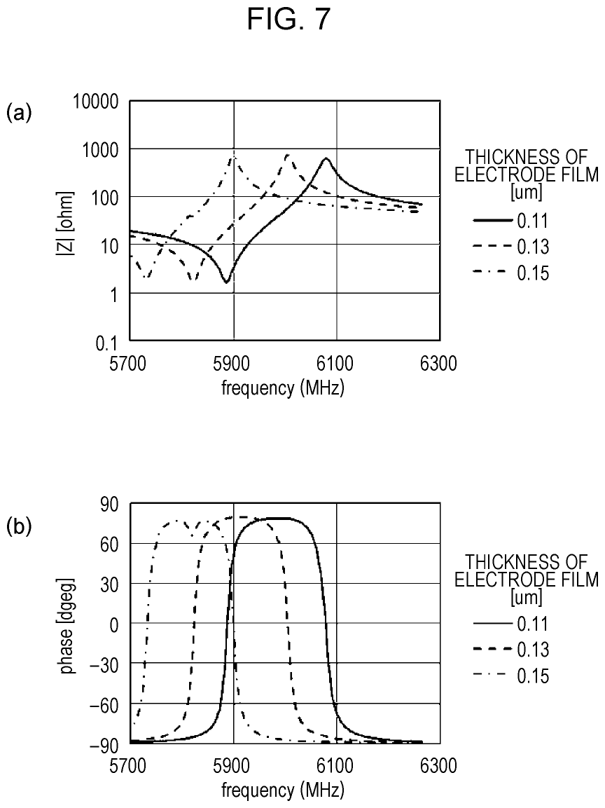

Frequency adjustment based on the thickness of the conductive layer 9 will be described next. FIG. 7(a) and FIG. 7(b) illustrate impedance characteristics and phase characteristics obtained when the thickness of the conductive layer 9 is changed in steps of 0.02 μm (in steps of 1% in the ratio to the wavelength) in the resonator 15. In FIG. 7, the horizontal axis represents the frequency (unit: MHz), and the vertical axis represents the impedance (unit: ohm) in FIG. 7(a) and the phase (unit: deg) in FIG. 7(b). As is apparent from FIG. 7, it is confirmed that although the resonant frequency can be shifted by changing the thickness of the conductive layer 9, a ripple occurs between the resonant frequency and the anti-resonant frequency when the thickness of the conductive layer 9 is increased. Accordingly, the difference in film thickness of the conductive layer 9 between the resonator 15H and the resonator 15L may be suppressed within ±1% in the ratio to the wavelength (within ±2% in the ratio to the pitch). In such a case, the influence of spurious can be reduced.

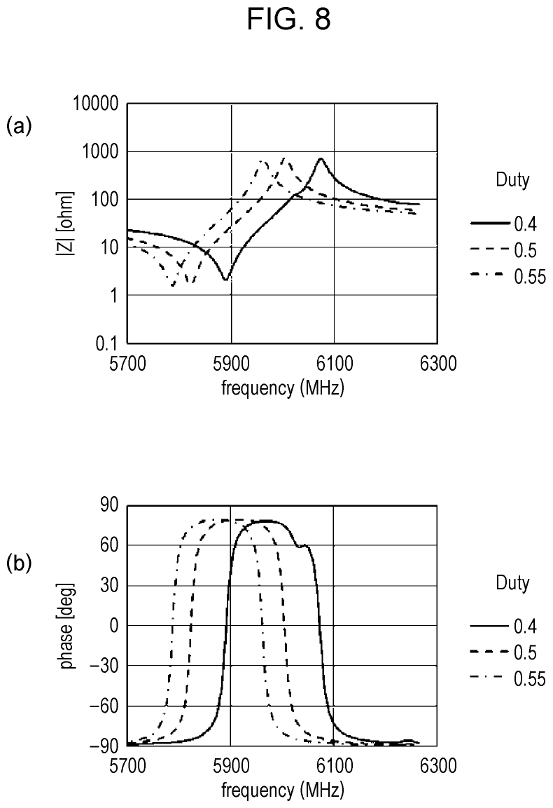

Frequency adjustment based on the duty of the electrode fingers 27 will be discussed next. FIG. 8(a) and FIG. 8(b) illustrate impedance characteristics and phase characteristics obtained when the duty is changed in the resonator 15. As is apparent from FIG. 8, it is confirmed that the resonant frequency shifts toward the lower frequency side as the duty increases. Specifically, by increasing the duty by 0.1, the resonant frequency can be shifted toward the lower frequency side by 60 MHz. It is confirmed that a ripple occurs near the anti-resonant frequency when the duty is set to 0.4. Accordingly, the duty may be adjusted in a range from 0.5 to 0.55 in addition to changing the thickness of the protective film 37.

As described above, when the electrode film thickness, the pitch, and the duty are changed, adjustment for reducing the influence of spurious is needed. When the electrode film thickness, the pitch, and the duty are changed without adjustment for reducing the influence of spurious, the ranges in which the electrode film thickness, the pitch, and the duty can be changed narrow. However, when the thickness of the protective film 37 is changed, the influence of spurious is small. This thus makes the design easier.

### Second Modification

In the example described above, the configuration of the ladder filter is not limited particularly. The elastic wave device 1 may be used when a filter having a wide passband is formed. Specifically, the elastic wave device 1 is used in a filter for which the anti-resonant frequency of the series resonators 15S is located on the lower frequency side of the resonant frequency of the parallel resonators 15P. This is because it is difficult to adjust the frequency only by the frequency adjustment based on the pitch p in this case.

The elastic wave device 1 may be used when the IDT electrodes 19 are formed on the affixed substrate 2 so that the rate of change of the frequency in response to a change of the pitch p by 10% is less than or equal to 10%. The elastic wave device 1 may be used when the IDT electrodes 19 are formed on the affixed substrate 2 so that the rate of change of the frequency in response to a change of the pitch p by 10% is less than or equal to 5%.

In the example described above, the thickness of the protective film 37 is set differently between the series resonators and the parallel resonators of the ladder filter. However, the configuration is not limited to this. For example, the thickness of the protective film 37 may be set differently between two filters that form different passbands or between a filter and a resonator connected to the filter.

### Third Modification

In the example described above, the case where LT is used as the piezoelectric layer 7 has been described by way of example. However, LN may be used. It is confirmed that the frequency can be similarly adjusted by changing the thickness of the protective film 37 also when LN is used as the piezoelectric layer 7. It is also confirmed that the waveform does not distort even if the thickness of the protective film 37 is set differently as in the case of LT.

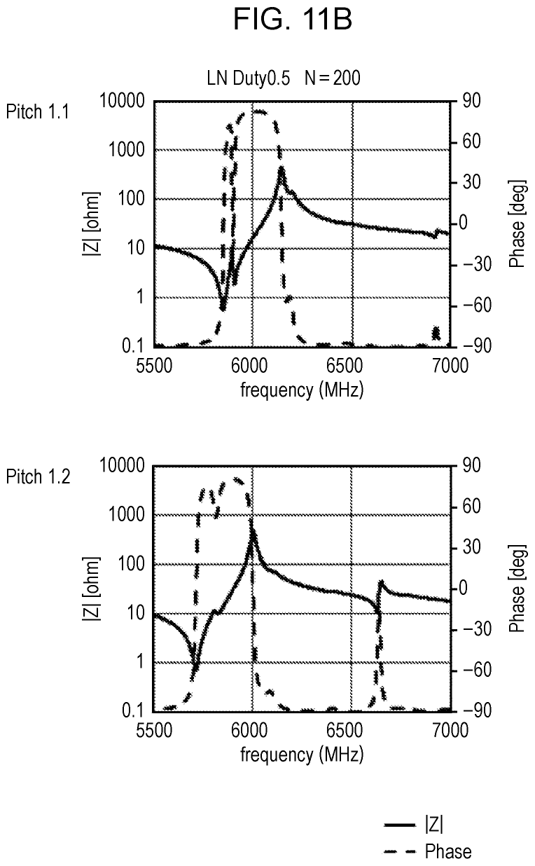

FIG. 11 (FIG. 11A and FIG. 11B) illustrates frequency characteristics obtained when LN is used as the piezoelectric layer 7 and the pitch of the electrode fingers 27 is changed. That is, FIG. 11 is a diagram corresponding to FIG. 6. FIG. 11A illustrates characteristics obtained when the pitch is set to 0.8 μm (0.8p when 1.0 μm is set as a reference), 0.9 μm (i.e., 0.9p), and 1.0 μm (i.e., p). FIG. 11B illustrates characteristics obtained when the pitch is set to 1.1 μm (1.1p when 1.0 μm is set as the reference) and 1.2 μm (i.e., 1.2p).

As is apparent from FIG. 11, it is more difficult to adjust the frequency based on the pitch of the electrode fingers 27 when LN is used as the piezoelectric layer 7 than when LT is used. That is, it is confirmed that the pitch can be adjusted in a range from 0.9p to 1.0p and that if the pitch is changed beyond this range, many ripples occur and the waveform distorts.

(Application Example of Elastic Wave Device: Splitter)

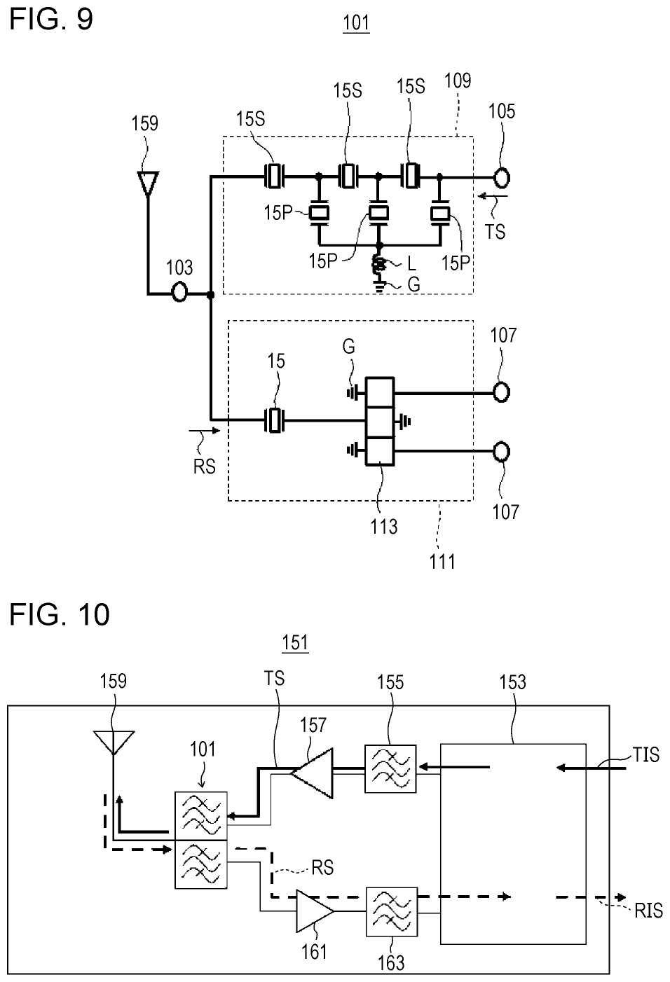

FIG. 9 is a circuit diagram schematically illustrating a configuration of a splitter 101 serving as an application example of the elastic wave device 1. As is understood from the reference signs illustrated in the upper left part of this figure on paper, the comb-teeth electrodes 23 and the reflectors 21 are illustrated in a simplified manner in this figure.

The splitter 101 includes, for example, a transmission filter 109 and a reception filter 111. The transmission filter 109 performs filtering on a transmission signal supplied from a transmission terminal 105 and outputs the resultant signal to an antenna terminal 103. The reception filter 111 performs filtering on a reception signal supplied from the antenna terminal 103 and outputs the resultant signal to a pair of reception terminals 107.

The transmission filter 109 is constituted by a ladder filter in which the plurality of resonators 15 are connected to each other in a ladder form, for example. That is, the transmission filter 109 includes the plurality of (or may be one) resonators 15 connected in series with each other between the transmission terminal 105 and the antenna terminal 103, and the plurality of (or may be one) resonators 15 (parallel arm) connecting the series line (series arm) and a reference potential to each other. The plurality of resonators 15 of the transmission filter 109 are disposed in or on the same affixed substrate 2 (3, 5, and 7), for example.

The reception filter 111 includes, for example, the resonator 15 and a multi-mode filter (including a double-mode filter.) 113. The multi-mode filter 113 includes the plurality of (three in the illustrated example) IDT electrodes 19 arranged in the elastic wave propagation direction, and a pair of reflectors 21 disposed on the respective sides. The resonator 15 and the multi-mode filter 113 of the reception filter 111 are disposed in or on the same affixed substrate 2, for example.

The transmission filter 109 and the reception filter 111 may be disposed on or in the same affixed substrate 2, or may be disposed on or in the different affixed substrates 2. FIG. 9 illustrates merely an example of the configuration of the splitter 101. For example, the reception filter 111 may be constituted by a ladder filter similarly to the reception filter 111.

The splitter 101 including the transmission filter 109 and the reception filter 111 has been described. However, the splitter 101 is not limited to this. The splitter 101 may be, for example, a diplexer or a multiplexer including three or more filters.

(Application Example of Elastic Wave Device: Communication Apparatus)

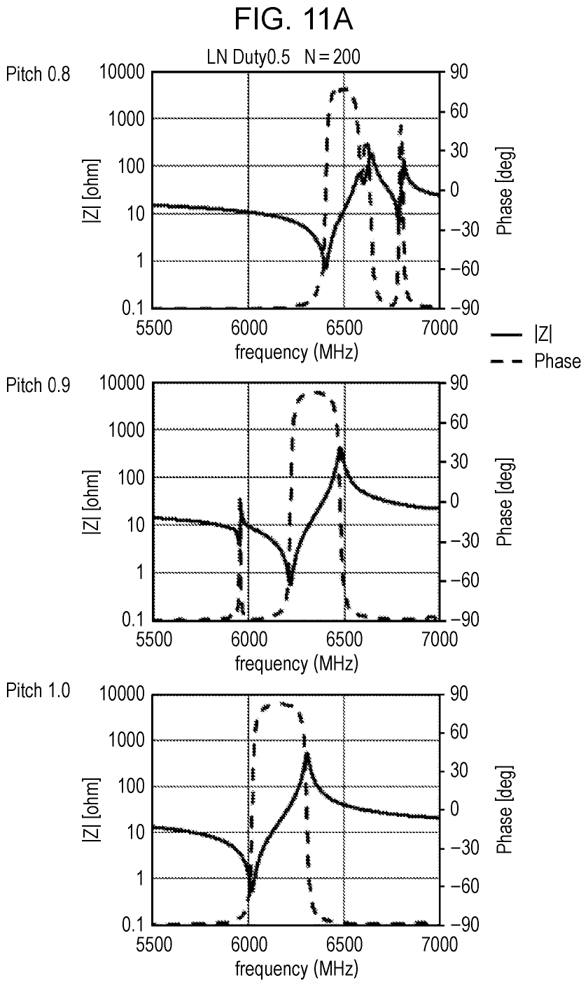

FIG. 10 is a block diagram illustrating major components of a communication apparatus 151 serving as an application example of the elastic wave device 1 (the splitter 101). The communication apparatus 151 performs wireless communication using a radio wave and includes the splitter 101.

In the communication apparatus 151, an RF-IC (Radio Frequency Integrated Circuit) 153 performs modulation and frequency up-conversion (conversion of a carrier frequency to a radio frequency signal) on a transmission information signal TIS including information to be transmitted, to generate a transmission signal TS. Unnecessary components in a band other than a transmission passband are removed by a band pass filter 155 from the transmission signal TS. The resultant transmission signal TS is amplified by an amplifier 157 and is input to the splitter 101 (the transmission terminal 105). The splitter 101 (the transmission filter 109) then removes unnecessary components in a band other than the transmission passband from the input transmission signal TS, and outputs the resultant transmission signal TS from the antenna terminal 103 to an antenna 159. The antenna 159 converts the input electric signal (transmission signal TS) into a radio signal (radio wave) and transmits the radio signal.

In the communication apparatus 151, a radio signal (radio wave) received by the antenna 159 is converted into an electric signal (reception signal RS) by the antenna 159, and the reception signal RS is input to the splitter 101 (the antenna terminal 103). The splitter 101 (the reception filter 111) removes unnecessary components in a band other than a reception passband from the input reception signal RS and outputs the resultant reception signal RS from the reception terminals 107 to an amplifier 161. The output reception signal RS is amplified by the amplifier 161, and unnecessary components in a band other than the reception passband are removed by a band pass filter 163. The RF-IC 153 then performs frequency down-conversion and demodulation on the reception signal RS to generate a reception information signal RIS.

The transmission information signal TIS and the reception information signal RIS may be low frequency signals (baseband signals) including appropriate information and are, for example, analog audio signals or digitized audio signals. The passband of the radio signal may be appropriately set. In the present embodiment, a passband of a relatively high frequency (for example, 5 GHz or higher) is also possible. The modulation scheme may be any of phase modulation, amplitude modulation, frequency modulation, or any combination of two or more of these. FIG. 17 illustrates a circuit for a direct conversion scheme. However, the circuit may be for another appropriate scheme and may be, for example, for a double superheterodyne scheme. FIG. 10 schematically illustrates the major components alone. Thus, a low pass filter, an isolator, or the like may be added at an appropriate position, or the position of the amplifier or the like may be changed.

The present disclosure is not limited to the embodiment above, and may be carried out in various forms. For example, the thickness of each layer and the Euler angles of the piezoelectric layer may be set to values outside the ranges exemplified in the embodiment. In the present disclosure, an example of the ladder filter is presented. However, the configuration may be used in a band elimination filter. In such a case, characteristics can be maintained even if the loss increases as long as spurious is not present. Thus, the protective film 37 may be adjusted more flexibly. Another bandpass filter may be combined with this band elimination filter to provide a single bandpass filter.

### REFERENCE SIGNS LIST

1 . . . elastic wave device, 3 . . . substrate, 5 . . . multilayer film, 7 . . . piezoelectric layer, 19 . . . IDT electrode, 11 . . . low acoustic impedance layer, 13 . . . high acoustic impedance layer, 37 . . . protective film.

1. An elastic wave device comprising:
a substrate;
a multilayer film located on the substrate, the multilayer film including a low acoustic impedance layer and a high acoustic impedance layer that are alternately stacked;
a piezoelectric layer located on the multilayer film;
a plurality of resonators located on the piezoelectric layer, the plurality of resonators including an IDT electrode; and
a protective film located on the plurality of resonators,
wherein the plurality of resonators comprise a first resonator and a second resonator that have different resonant frequencies, and the first resonator has a lower resonant frequency than the second resonator, and
wherein a thickness of the protective film on the second resonator is larger than the thickness of the protective film on the first resonator.

2. The elastic wave device according to claim 1,
wherein the piezoelectric layer has a thickness of 0.6p or smaller, where p denotes a pitch of electrode fingers of the IDT electrode.

3. The elastic wave device according to claim 1,
wherein the second resonator is used as a series resonator of a ladder filter, and the first resonator is used as a parallel resonator of the ladder filter.

4. The elastic wave device according to claim 3,
wherein the first resonator has an anti-resonant frequency that is located on a lower frequency side of a resonant frequency of the second resonator.

5. The elastic wave device according to claim 1,
wherein a rate of change of the resonant frequency in response to a change of a pitch of the electrode fingers of the IDT electrode by 10% is less than or equal to 10%.

6. The elastic wave device according to claim 1,
wherein the protective film has a thickness of 0.04p or smaller.

7. The elastic wave device according to claim 1,
wherein a rate of change between a pitch of the electrode fingers of the IDT electrode of the first resonator and a pitch of the electrode fingers of the IDT electrode of the second resonator is greater than a rate of change between the resonant frequency of the first resonator and the resonant frequency of the second resonator.

8. A splitter comprising:
an antenna terminal;
a transmission filter configured to perform filtering on a signal to be output to the antenna terminal; and
a reception filter configured to perform filtering on a signal input from the antenna terminal,
wherein at least one of the transmission filter or the reception filter includes the elastic wave device according to claim 1.

9. A communication apparatus comprising:
an antenna;
the splitter according to claim 8, the antenna terminal of the splitter being connected to the antenna; and
an IC connected to the transmission filter and the reception filter, on an opposite side from the antenna terminal in a signal path.
